(19) United States
(12) Patent Application Publication
(10) Pub. No.: US 2008/0068036 A1
(43) Pub. Date: Mar. 20, 2008

(54) SEMICONDUCTOR TEST SYSTEM CAPABLE OF VIRTUAL TEST AND SEMICONDUCTOR TEST METHOD THEREOF

(76) Inventors: Byong-Hui Yun, Yongin-si (KR); Ki-Myung Seo, Yongin-si (KR); Do-Hoon Byun, Suwon-si (KR)

Correspondence Address: F. CHAU & ASSOCIATES, LLC, 130 WOODBURY ROAD, WOODBURY, NY, 11797, US

(21) Appl. No.: 11/756,860

(22) Filed: Jun. 1, 2007

(30) Foreign Application Priority Data
Jun. 20, 2006 (KR) 2006-55560

(51) Int. Cl. G01R 31/02

(52) U.S. Cl. 324/763

(57) ABSTRACT

A semiconductor test system capable of performing a virtual test and a semiconductor test method thereof. The semiconductor test system includes a tester providing a test signal and an emulator providing a virtual test result to the tester in response to the test signal. The emulator includes virtual prober software to obtain the virtual test result.

### CROSS-REFERENCE TO RELATED APPLICATION

This U.S. non-provisional patent application claims priority under 35 U.S.C. §119 of Korean Patent Application No. 2006-55560, filed on Jun. 20, 2006, the entire contents of which are hereby incorporated by reference.

### BACKGROUND OF THE INVENTION

The present disclosure relates to a semiconductor test system and, more particularly, to a semiconductor test system capable of performing a virtual test and a semiconductor test method thereof.

The semiconductor test system is used to detect defects of a semiconductor device through an electrical test process. The semiconductor test system includes a tester and a prober, or, alternatively, a tester and a handler.

The semiconductor test system including the tester and the prober is used to remove an initial defect after a wafer manufacturing process. Typically, the prober is a wafer transferring device. The prober transfers the wafer so as to accurately deliver a test signal from the tester into a chip inside the wafer.

On the other hand, the semiconductor test system including the tester and the handler is used to remove defects after an assembling process. Typically, the handler is a package transferring device. The handler receives a test signal from the tester, and examines a packaged chip.

FIG. 1 is a block diagram of a conventional semiconductor test system. Referring to FIG. 1, a semiconductor test system 10 includes a tester 1 land a prober 12. The tester 11 generates a test signal for testing a wafer (not shown). The tester 11 provides the test signal into the prober 12. The prober 12 is a wafer transferring device, and transfers the next wafer when a test for one wafer is completed during a test operation.

The tester 11 drives the prober 12 to perform a wafer test operation. After reading a wafer test result, the tester 11 needs to be connected to the prober 12 to give an appropriate command depending on the wafer test result. The tester 11 and the prober 12 communicate with each, other through a general purpose interface bus (GPIB) or RS232 (not shown).

When the tester 11 is not actually connected to the prober 12, no operation is possible. According to a conventional semiconductor test system, when the tester is developed or the test program is updated, the prober needs to be set up and be connected to the tester.

### SUMMARY OF THE INVENTION

Exemplary embodiments of the present invention provide a semiconductor test system capable of a virtual test operation without connecting a prober to a tester, and a semiconductor test method thereof.

Exemplary embodiments of the present invention provide semiconductor test systems capable of performing a virtual, test without a prober, the semiconductor test systems including: a tester providing a test signal; and an emulator providing a virtual test result to the tester in response to the test signal. The emulator includes virtual prober software to obtain the virtual test result.

In exemplary embodiments, the emulator further includes test software receiving the test signal and generating a test command, the test software providing the test command to the virtual prober software. The test software and the virtual prober software communicate with each other through the Ethernet. The emulator further includes: a buffer memory storing a virtual test result and an error condition corresponding to the test command; and a monitor notifying a user of an error occurring during a virtual test operation.

In exemplary embodiments, the virtual prober software includes: an input/output unit receiving the test command and outputting the virtual test result; a process unit performing a virtual test operation in response to the test command; and a control unit controlling the buffer memory and the monitor during the virtual test operation. The control unit controls the monitor to notify a user of an error when there is an error in the test command, or in the virtual test result. The control unit also controls the monitor to notify a user of an error when there is an error in an application program of the virtual prober software,

According to exemplary embodiments of the present invention, semiconductor test systems include: a tester providing a test signal; a prober performing a wafer test operation; and an emulator performing a virtual test operation through virtual prober software. The emulator controls the prober to perform the wafer test operation in response to the test signal, or controls the virtual prober software to perform the virtual test operation.

In exemplary embodiments, the emulator further includes test software receiving the test signal and generating a test command, the test software selectively providing the test command to the prober or to the virtual prober software. The test software provides the test command to the virtual prober software when the virtual prober software is enabled. The prober communicates with the emulator through a GPIB (general purpose interface bus). The prober communicates with the emulator through the RS232 standard for serial binary data connection. The test software and the virtual software communicate with each, other through the Ethernet.

In exemplary embodiments, the emulator further includes: a buffer memory storing a virtual test result and an error condition corresponding to the test command; and a monitor notifying a user of an error occurring during a virtual test operation. The virtual prober software includes; an input/output unit receiving the test command and outputting the virtual test result: a process unit performing a virtual test operation in response to the test command; and a control unit controlling the buffer memory and the monitor during tire virtual test operation. The control unit controls the monitor to notify a user of an error when there is an error in the test command, or in the virtual test result. The control unit also controls the monitor to notify a user of an error when there is an error in an application program of the virtual prober software.

Exemplary embodiments of the present invention provide semiconductor test methods performing a virtual test operation without a prober, the methods including: generating a test signal by a tester; determining whether virtual prober software is enabled or not; performing a virtual test operation, through the virtual prober software in response to the test signal when the virtual prober software is enabled; and providing a virtual test result to the tester.

In exemplary embodiments, the method further includes performing a wafer test operation through a prober when the virtual prober software is disabled.

According to exemplary embodiments, the performing of the virtual test operation includes: confirming an input of the test signal; analyzing the test signal to determine whether there is an error or not; and performing the virtual test operation when there is no error. The method further includes notifying a user of an error when there is an error.

### BRIEF DESCRIPTION OF THE FIGURES

Exemplary embodiments of the present invention will be understood in more detail from the following descriptions taken in conjunction with the accompanying figures, in which;

FIG. 1 is a block diagram of a conventional semiconductor test system;

FIG. 2 is a block diagram of a semiconductor test system according to an exemplary embodiment of the present invention;

FIG. 3 is a block diagram of an operation of virtual prober software used in the system of FIG. 2;

FIG. 4 is a flowchart of a semiconductor test method according to an exemplary embodiment of the present invention;

FIG. 5 is a flow-chart illustrating an operation of determining whether there is error in an application program, of virtual prober software in operation S320 of FIG. 4; and

FIG. 6 is a flowchart illustrating an operation determining whether there is an error in a virtual test result in operation S320 of FIG. 4.

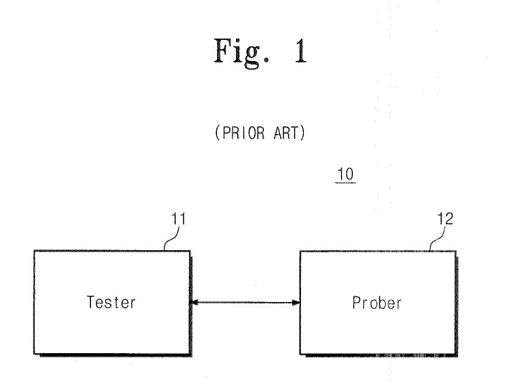

### DETAILED DESCRIPTION OF EXEMPLARY EMBODIMENTS

Exemplary embodiments of the present invention will be described below in more detail with reference to the accompanying drawings. The present invention may, however, be embodied in different forms and should not be construed as limited to the exemplary embodiments set forth herein. Rather, these exemplary embodiments are provided so that this disclosure will be thorough and complete, and will fully convey the scope of the present invention to those of ordinary skill in the art.

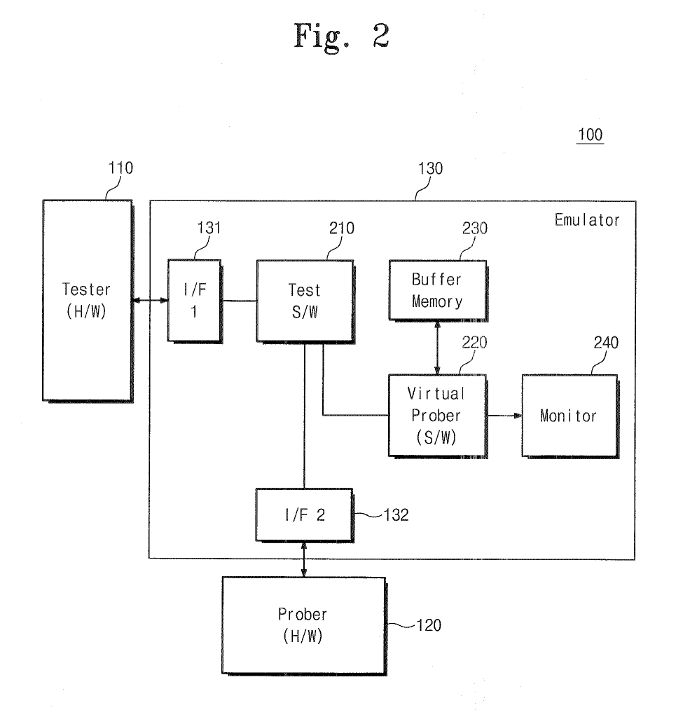

FIG. 2 is a block diagram of a semiconductor test system according to an exemplary embodiment of the present invention. Referring to FIG. 2, a semiconductor test system. 100 includes a tester 110, a prober 120, and an emulator 130. According to the semiconductor test system 100, although the tester 110 does not include the prober 120 therein, it can operate as if connected to the prober 120.

The tester 110 in the form of hardware (H/W) applies an electric signal to a semiconductor chip placed on a wafer (not shown) to test electric characteristics of the semiconductor chip. The prober 120 in the form of hardware (H/W) operating as a wafer transferring device places a wafer on an appropriate point of a chuck (not shown). Generally, an electric signal of the tester 110 is transferred into the wafer of the prober 120, and the tester 110 reads a test result from the prober 120 to determine whether there is a defect on the wafer or not.

The tester drives the prober 120, and needs to be actually connected to the prober 120 to examine defects of the wafer. That is, the tester 110 can not read data without the prober 120, such that it can not perform a normal test operation. The semiconductor test system 100 of this exemplary embodiment of the present invention, however, includes the emulator 130 and can perform a virtual test operation as if there is the prober 120.

Referring to FIG. 2, the emulator 130 includes a first interface 131 for the tester 110, and a second interface 132 for the prober 120. In this exemplary embodiment, the second interface 132 uses a communication method such as a general purpose interface bus (GPIB) or the RS232 standard for serial binary data connection. The emulator 130 further comprises test software 210 (S/W), virtual prober software 210 (S/W), a buffer memory 230, and a monitor 240.

The test software 210 is an operating system software of the tester 110. The test software 210 receives an electric signal from the tester 110 through the first interface 131. The test software 210 generates a test command by using the electric signal of the tester 110. The test command is provided to the prober 120 through the second interface 132 or to the virtual prober software 220.

In an exemplary embodiment the test software 210 provides a test command to the virtual prober software 220 when the virtual prober software 220 is in an enable state. In this case, a virtual test operation is performed. When the virtual prober software 220 is in a disable state, however, the test software 210 provides a test command to the prober 120. In this case, a real test operation is performed.

The prober software 220 is connected to the test software 210 through the Ethernet. Besides the Ethernet, the prober software 220 may also be connected to the test software 210 through semaphores, a local area network, and a message queue.

The virtual prober software 220 receives a test command from the test software 210 during a virtual test operation. The virtual prober software 220 performs a virtual test operation in response to the test command. The virtual test result is delivered into the test software 210 again. The virtual prober software 220 emulates the prober 120 as if an actual prober 120 operates. The virtual prober software 220 virtually generates data identical to that from the actual prober 120 and then sends the data into the test software 210.

Since the tester 110 determines testing of a device by using data, it can not distinguish an actual test result outputted from the actual prober 120 from a virtual test result outputted from the emulator 130. A buffer memory 230 of the emulator 130 includes a plurality of commands corresponding to various test signals of the tester 110 and their processed results, such that the emulator 130 emulates the actual prober 120.

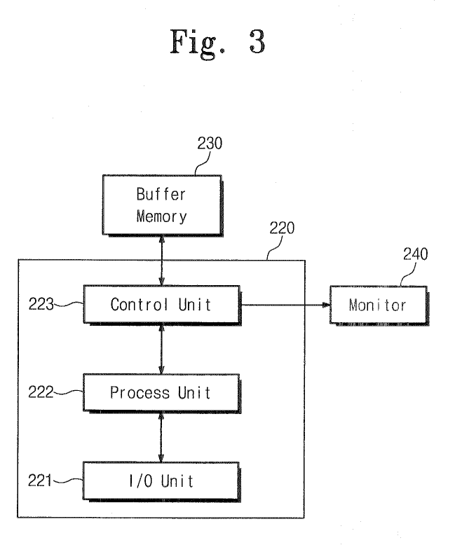

FIG. 3 is a block diagram of an operation of the virtual prober software 220 of FIG. 2. Referring to FIG. 3, the virtual prober software 220 includes an input/output unit 221, a process unit 222, and a control unit 223.

The process unit 221 analyzes the test command inputted through the input/output unit 221. That is, the process unit 221 determines whether a new test command is inputted from tire input/output unit 221, and whether the inputted test command is suitable for a predetermined format. The process unit 221 delivers the virtual test result into the input/output unit 221.

The control unit 222 controls the buffer memory 230 or the monitor 240 according to the processed result of the process unit 221. The control unit 222 notifies a user of an error situation when there is an error in an inputted test command or when there is an error in the virtual test result. Although a monitor 240 is illustrated in FIGS. 2 and 3, it is apparent to those of ordinary skill in the art that other means, such as an alarm, a printer, and the like can be used for notification. On the other hand, the buffer memory 230 includes various test commands, virtual test process results for respective test commands, and expected error situations.

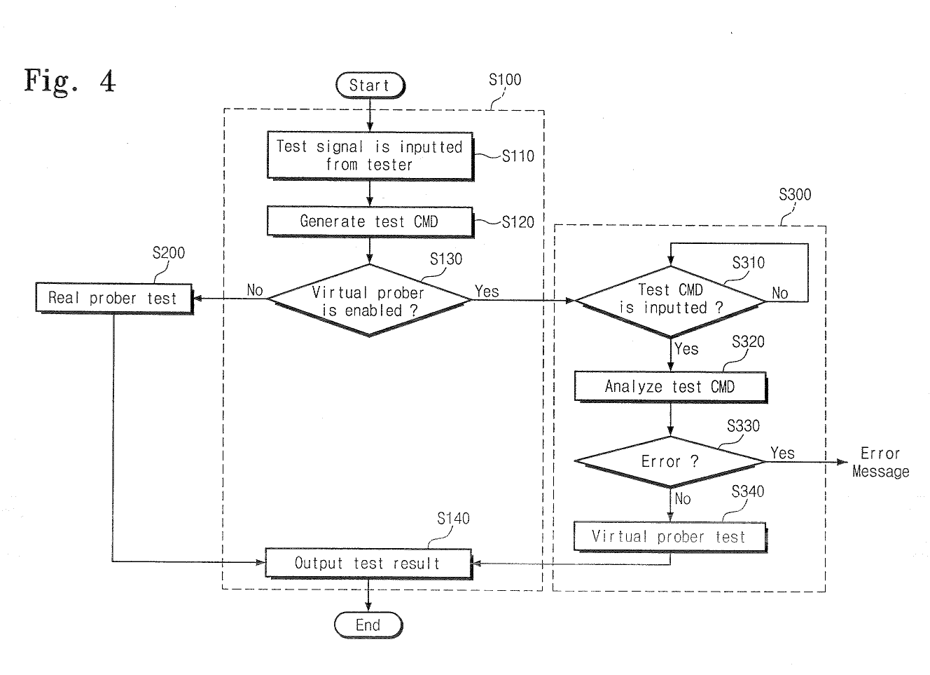

FIG. 4 is a flowchart of a semiconductor test method according to an exemplary embodiment of the present invention. Referring to FIG. 4, a test method of a semiconductor test system is divided into an actual prober test operation in S200 and a virtual test operation in S300.

First, the test software 210 of FIG. 2 will be described. In operation S110, the test software 210 receives a test signal from the tester 110 of FIG. 2. In operation S120, the test software 210 generates a test command in response to the test signal. In operation S130, it is determined whether the virtual prober software 220 of FIG. 2 is in an enable state.

When the virtual prober software 220 is not in the enable state, that is, No, a test command is applied to the actual prober 120 of FIG. 2. In this case, the actual prober operation is performed in operation S200. When the virtual prober software 220 is in the enable state, that is, Yes, a test command is applied to the virtual prober software 220. In this case, a virtual prober test operation is performed in operation S300.

Next an operation of the virtual prober software 220 is described. In operation S310, the virtual prober software 220 determines whether a test command is inputted from the test software 210. An operation S310 repeats until the test command is inputted, and it proceeds to an operation S320 when the test command is inputted,

In operation S320, the process unit 222 of FIG. 3 of the virtual prober software 220 analyzes the test command. The process unit 222 compares the test command stored in the buffer memory 230 of FIG. 3 to a new inputted test command to verify whether there is an error in the test command itself.

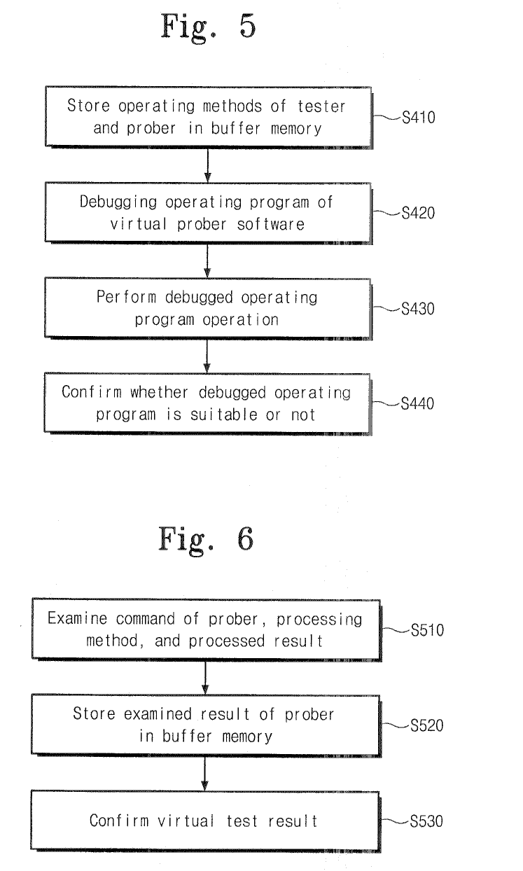

In this exemplary embodiment, the process unit 222 detects the test result stored in the buffer memory 230 in response to the test command. The process unit 222 verifies whether there is an error in the virtual test result. This will be described in more detail with reference to FIG. 6. On the other hand, it is determined whether there is an error in an operating system of the virtual prober software in operation S320. This will be described in more detail with reference to FIG. 5.

In operation S330, the virtual prober software 220 determines whether there was an error in operation S320. When there is an error in operation S320, that is, Yes, the control unit 223 of FIG. 3 sends an error message to the monitor 240, or whatever other device is used to inform the user. The monitor 240 notifies the user of an error situation, in response to the error message. When there is no error, that is, No, however, the process unit 222 performs the virtual prober test operation S340, and sends the virtual test results into the test software 210.

In operation S140, the test software 210 sends the actual test result provided from the actual prober 120 or tire virtual test result provided from the virtual prober software 220 into the tester 110 and ends.

FIG. 5 is a flowchart illustrating an operation determining whether there is error in an application program of a virtual prober software in operation S320 of FIG. 4. In operation S410, parameters such as test and prober operating methods, commands in use, and error situations are stored in the buffer memory 230 of FIG. 2. In operation S420, an application program of the virtual prober software that processes data as if there is the prober 120 is debugged. In operation S430, the application program of the debugged virtual prober software operates. In operation S440, it is confirmed whether the application program of the debugged virtual prober software is compatible.

FIG. 6 is a flowchart illustrating an operation of determining whether there is an error in a virtual test result in operation S320 of FIG. 4. In operation S510, commands of the prober, their processing methods, and their processed results are examined. In operation S520, the examined prober results are stored in the buffer memory 230 of FIG. 2. In operation S530, the compatibility of the virtual test result is confirmed.

A conventional semiconductor test system requires an actual prober for driving tests. Additionally, a wafer is loaded in the actual prober. Accordingly, when conventionally developing a test or a test program, the prober needs to be set up. The semiconductor test system of the exemplary embodiment of the present invention, however, outputs a virtual test result as if the actual prober is installed without actually doing so. According to exemplary embodiments of the present invention, the inconvenience such as an actual prober setup during test or test program development and connection for the test may be resolved.

The semiconductor test system of the exemplary embodiment of the present invention outputs a test result as if the actual prober is installed, without the actual prober having to be installed. According to the exemplary embodiment of the present invention, an actual prober setup during test or test program development can be eliminated.

The above-disclosed subject matter is to be considered illustrative, and not restrictive, and the appended claims are intended to cover all such modifications, enhancements, and other exemplary embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A semiconductor test system for performing a virtual test without a prober, the semiconductor test system comprising:
a tester providing a test signal; and
an emulator providing a virtual test result to the tester in response to the test signal,
wherein the emulator includes virtual prober software to obtain the virtual test result,

2. The semiconductor test system of claim 1, wherein the emulator further comprises test software receiving the test signal and generating a test command, the test software providing the test command to the virtual prober software.

3. The semiconductor test system of claim 2, wherein the test software and the virtual prober software communicate with each other through the Ethernet.

4. The semiconductor test system of claim 2, wherein the emulator further comprises:
a buffer memory storing the virtual test result and an error condition corresponding to the test command; and
a monitor notifying a user of an error occurring during a virtual test operation.

5. The semiconductor test system of claim 4, wherein the virtual prober software comprises:
an input/output unit receiving the test command and outputting the virtual test result;
a process unit performing a virtual test operation in response to the test command; and
a control unit controlling the buffer memory and the monitor during the virtual test operation.

6. The semiconductor test system, of claim 5, wherein, the control unit controls the monitor to notify a user of an error when there is an error in the test command or in the virtual test result.

7. The semiconductor test system of claim 5, wherein the control unit controls the monitor to notify a user of an error when there is an error in an application program of the virtual prober software.

8. A semiconductor test system comprising:
a tester providing a test signal;
a prober performing a wafer test operation; and
an emulator performing a virtual test operation through virtual prober software,
wherein the emulator controls the prober to perform the wafer test operation in response to the test signal, or controls the virtual prober software to perform the virtual test operation.

9. The semiconductor test system of claim 8, wherein the emulator further comprises test software receiving the test signal and generating a test command, the test software selectively providing the test command to the prober or to the virtual prober software.

10. The semiconductor test system of claim 9, wherein the test software provides the test command to the virtual prober software when the virtual prober software is enabled.

11. The semiconductor test system of claim 9, wherein the prober communicates with the emulator through a general purpose interface bus.

12. The semiconductor test system of claim 9, wherein the prober communicates with the emulator through an RS232 standard for serial binary data connection.

13. The semiconductor test system of claim 9, wherein the test software and the virtual software communicate with each other through the Ethernet.

14. The semiconductor test system of claim 9, wherein the emulator further comprises:
a buffer memory storing a virtual test result and an error condition corresponding to the test command; and
a monitor notifying a user of an error occurring during a virtual test operation.

15. The semiconductor test system of claim 14, wherein the virtual prober software comprises:
an input/output unit receiving the test command and outputting the virtual test result;
a process unit performing a virtual test operation in response to the test command; and
a control unit controlling the buffer memory and the monitor during the virtual test operation.

16. The semiconductor test system of claim 15, wherein the control unit controls the monitor to notify a user of an error when there is an error in the test command or in the virtual test result.

17. The semiconductor test system of claim 15, wherein the control unit controls the monitor to notify a user of an error when there is an error in an application program of the virtual prober software.

18. A semiconductor test method performing a virtual test operation without a prober, the method comprising:
generating a test signal by a tester;
determining whether virtual prober software is enabled;
performing a virtual test operation through the virtual prober software in response to the test signal when the virtual prober software is enabled; and
providing a virtual test result to the tester.

19. The method of claim 18, further comprising performing a wafer test operation through a prober when the virtual prober software is disabled.

20. The method of claim 18, wherein the step of performing the virtual test operation comprises:
confirming an input of the test signal;
analyzing the test signal to determine whether there is an error; and
performing the virtual test operation when there is no error.

21. The method of claim 20, further comprising notifying a user of an error when there is an error.
